(19) United States
(12) Patent Application Publication
(10) Pub. No.: US 2016/0013347 A1
(43) Pub. Date: Jan. 14, 2016

(54) Solar Cell Array

(71) Applicant: Sergio W. Weffer, Salt Lake City, UT (US)

(72) Inventor: Sergio W. Weffer, Salt Lake City, UT (US)

(21) Appl. No.: 14/329,585

(22) Filed: Jul. 11, 2014

(51) Int. Cl. H01L 31/054

(52) U.S. Cl. CPC H01L 31/0543

(57) ABSTRACT

An array for solar cell arrangement whereby light is more efficiently captured is disclosed herein. The array is a collection of a plurality of chambers, lined with solar cells. Each chamber has a lens positioned therein to direct light into the chamber. Most light reflected by one solar cell within each chamber will then be directed to another, increasing the use of captured light.

### FIELD OF THE INVENTION

The present invention relates to the field of solar energy and more particularly relates to an arrangement of solar cells and lenses for efficient collection and conversion of light into electricity.

### BACKGROUND OF THE INVENTION

Solar energy is one of the many “green technologies” being developed in an effort to replace fossil fuels. The concept of a solar cell is simple. Photons from a light source, usually the sun, strike a solar cell and create electricity by what is called the photovoltaic effect. The solar cell is usually comprised of an N-type semiconductor layered over a P-type semiconductor. When struck by photons, free electrons are created as are positive holes in their respective semiconductors. This imbalance creates a current which may be used to power anything electrical, provided there are enough solar cells to provide adequate electricity for the job.

Maximizing the light that strikes the solar cell will increase power output in a manner dependent upon the efficiencies of the cell and its composition. Much light is reflected from the solar cell structure and by capturing this reflected light more electricity may be generated by a solar cell.

The present invention is an arrangement of solar cells and lenses that decreases the amount of reflected light and directs more light to individual solar cells for generation of electricity.

The present invention represents a departure from the prior art in that the arrangement of the present invention allows for light to be trapped within a collection of grouped solar cells, thus utilizing more of the light as an energy source.

### SUMMARY OF THE INVENTION

In view of the foregoing disadvantages inherent in the known types of solar cells, this invention provides a solar cell array with a lens to trap useful light in a manner that increases exposure of light to solar cells. As such, the present invention's general purpose is to provide a new and improved solar cell array that is easily implemented and constructed and is economically advantageous in use.

To accomplish these objectives, the solar cell array comprises plurality of solar cells arranged in a chamber, with one side open to the light source. A lens is positioned within the chamber so as to collect as much light as possible and direct it to the solar cells. Once in the chamber, light reflected from one solar cell will be collected by another as each cell faces at least one other, increasing photon utilization.

The more important features of the invention have thus been outlined in order that the more detailed description that follows may be better understood and in order that the present contribution to the art may better be appreciated. Additional features of the invention will be described hereinafter and will form the subject matter of the claims that follow.

Many objects of this invention will appear from the following description and appended claims, reference being made to the accompanying drawings forming a part of this specification wherein like reference characters designate corresponding parts in the several views.

Before explaining at least one embodiment of the invention in detail, it is to be understood that the invention is not limited in its application to the details of construction and the arrangements of the components set forth in the following description or illustrated in the drawings. The invention is capable of other embodiments and of being practiced and carried out in various ways. Also it is to be understood that the phraseology and terminology employed herein are for the purpose of description and should not be regarded as limiting.

As such, those skilled in the art will appreciate that the conception, upon which this disclosure is based, may readily be utilized as a basis for the designing of other structures, methods, and systems for carrying out the several purposes of the present invention. It is important, therefore, that the claims be regarded as including such equivalent constructions insofar as they do not depart from the spirit and scope of the present invention.

### BRIEF DESCRIPTION OF THE DRAWINGS

FIG. 1 is a top plan view of an array of solar cells and lenses according to the present invention.

FIG. 2 is a sectional view of the array of FIG. 1, taken along line A-A.

FIG. 3 is a perspective, exploded view of a chamber utilized in the array of FIG. 1.

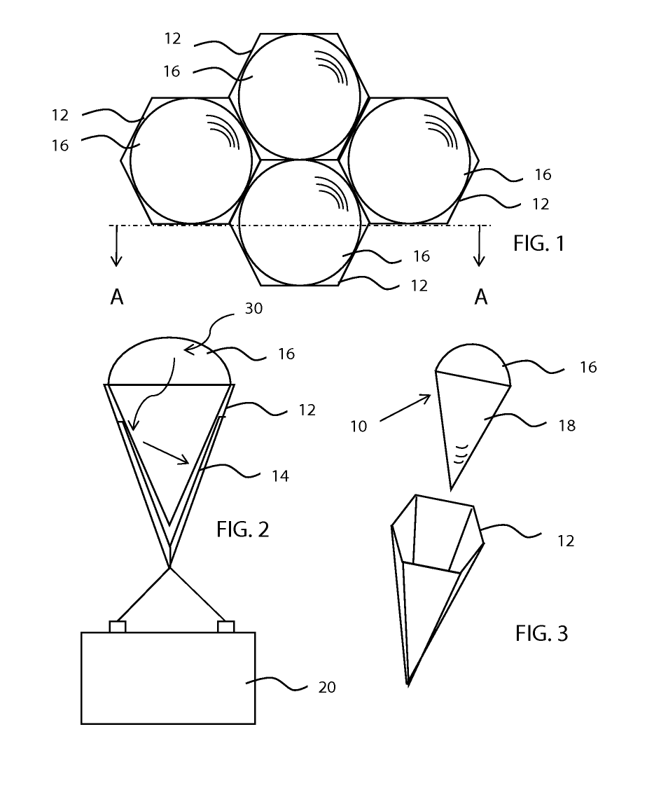

### DETAILED DESCRIPTION OF THE PREFERRED EMBODIMENT

With reference now to the drawings, the preferred embodiment of the solar cell array is herein described. It should be noted that the articles “a”, “an”, and “the”, as used in this specification, include plural referents unless the content clearly dictates otherwise.

With reference to the Figures, the array is comprised of a plurality of solar cell chambers 12, each with a lens nested therein. Each chamber 12 is formed in a manner of an upside down pyramid while the lenses 10 are then made conical, with a domed head 16 and a trailing cone 18 so as to fit therein. The chambers 12 are depicted as regular hexagons, though any regular shape, including polygons and ellipses, could maximize coverage of a surface could be used. Regular polygons of more than five sides are preferred as these shapes comport more easily and completely with the conical lens 10 while also minimizing open space between the chambers 14. The interior of each chamber 12 is lined with solar cells 14.

In use, more particularly seen in FIG. 2, a beam of light 30 is captured by the dome 16 of lens 10 and directed downward, into the chamber 12. Photons in the beam 30 are collected by one solar cell 14, but some are inevitably reflected. These photons are then naturally directed to another cell 14 within the chamber 12, increasing the use of the light for the photovoltaic effect. Electricity generated by solar cells 14 may then be used as it would for any other solar powered operation, be it powering an electrical device or stored. These applications are represented generically by battery 20, and it is to be understood that the battery 20 represents a myriad of possibilities well within the experience of the person of ordinary skill in the art to utilize electricity, be it as DC power or coupled to an inverter for AC power. It is also to be understood that linking solar cells together is also within the purview of those skilled in the art and, as such, each individual chamber 12 is not shown linked to the same battery. Lens construction and materials will be dependent upon the effects and choices of a designer and may incorporate any known or later discovered materials or techniques for such construction.

Although the present invention has been described with reference to preferred embodiments, numerous modifications and variations can be made and still the result will come within the scope of the invention. No limitation with respect to the specific embodiments disclosed herein is intended or should be inferred.

What is claimed is:

1. A solar cell array comprising:
a. a plurality of chambers, each chamber having a side open to a light source and lined with a plurality of solar cells;
b. a plurality of lenses, residing within the chambers,
wherein, light is captured by the lenses and directed into each lens' corresponding chamber.

2. The solar cell array of claim 1, each chamber being an inverted pyramid extended from a regular polygon, the base of which is the open side, and each lens being conical in a manner to fit within each chamber.

3. The solar cell array of claim 2, the regular polygon having more than five sides.
